(19) United States
(12) Patent Application Publication
(10) Pub. No.: US 2010/0218821 A1
(43) Pub. Date: Sep. 2, 2010

(54) SOLAR CELL AND METHOD FOR MANUFACTURING THE SAME

(76) Inventors: Sunyoung KIM, Seoul (KR); Choul KIM, Seoul (KR); Youngho CHOE, Seoul (KR)

Correspondence Address: BIRCH STEWART KOLASCH & BIRCH, PO BOX 747, FALLS CHURCH, VA, 22040-0747, US

(21) Appl. No.: 12/713,487

(22) Filed: Feb. 26, 2010

(30) Foreign Application Priority Data
Mar. 2, 2009 (KR) 10-2009-0017736
Jan. 5, 2010 (KR) 10-2010-0000368

(51) Int. Cl. H01L 31/00

(52) U.S. Cl. 136/256

(57) ABSTRACT

A solar cell and a method for manufacturing the same are disclosed. The solar cell includes a substrate having a first conductive type, at least one impurity region connected to the substrate, a passivation layer positioned on the at least one impurity region, the passivation layer including at least one opening exposing a portion of the at least one impurity region, the at least one opening having at least one straight portion, a first electrode connected to the exposed portion of the at least one impurity region exposed through the at least one opening, and a second electrode connected to the substrate.

This application claims priority to and the benefit of Korean Patent Application No. 10-2009-0017736 filed in the Korean Intellectual Property Office on Mar. 2, 2009 and Korean Patent Application No. 10-2010-0000368 filed in the Korean Intellectual Property Office on Jan. 5, 2010, the entire contents of which are incorporated herein by reference.

### BACKGROUND OF THE INVENTION

1. Field of the Invention

Embodiments of the invention relate to a solar cell and a method for manufacturing the same.

2. Description of the Related Art

Recently, as existing energy sources such as petroleum and coal are expected to be depleted, interests in alternative energy sources for replacing the existing energy sources are increasing. Among the alternative energy sources, solar cells generating electric energy from solar energy have been particularly spotlighted. A silicon solar cell generally includes a substrate and an emitter layer, each of which is formed of a semiconductor, and a plurality of electrodes respectively formed on the substrate and the emitter layer. The semiconductors forming the substrate and the emitter layer have different conductive types, such as a p-type and an n-type. A p-n junction is formed at an interface between the substrate and the emitter layer.

When light is incident on the solar cell, a plurality of electron-hole pairs are generated in the semiconductors. The electron-hole pairs are separated into electrons and holes by the photovoltaic effect. Thus, the separated electrons move to the n-type semiconductor (e.g., the emitter layer) and the separated holes move to the p-type semiconductor (e.g., the substrate), The electrons and holes are respectively collected by the electrode electrically connected to the emitter layer and the electrode electrically connected to the substrate. The electrodes are connected to one another using electric wires to thereby obtain electric power.

The electrode connected to the emitter layer and the electrode connected to the substrate may be respectively positioned on an incident surface of the substrate on which light is incident and a surface of the substrate, opposite the incident surface, on which light is not incident. Alternatively, the electrode connected to the emitter layer and the electrode connected to the substrate may be positioned on the surface of the substrate opposite the incident surface.

When all of the electrodes connected to the emitter layer and the substrate are positioned on the surface of the substrate opposite the incident surface, an incident area of light increases. Hence, efficiency of the solar cell is improved.

### SUMMARY OF THE INVENTION

Embodiments of the invention provide a solar cell and a method for manufacturing the same capable of improving carrier transmission efficiency.

Embodiments of the invention provide a solar cell and a method for manufacturing the same capable of improving efficiency.

In one aspect, there is a solar cell including a substrate having a first conductive type, at least one impurity region connected to the substrate, a passivation layer positioned on the at least one impurity region, the passivation layer including at least one opening exposing a portion of the at least one impurity region, the at least one opening having a shape having at least one straight portion, a first electrode connected to the exposed portion of the at least one impurity region exposed through the at least one opening, and a second electrode connected to the substrate.

The at least one opening may have at least two straight portions and at least two curved portions connected to the at least two straight portions.

Lengths of opposite sides of the at least one opening may be equal to or different from each other.

A length ratio of one of the at least two straight portions and two curved portions of the at least two curved portions connected to the one straight portion may be approximately 1:49.5:49.5 to 98:1:1.

The passivation layer may include a plurality of openings, and the plurality of openings may be formed along the at least one impurity region.

The plurality of openings may be formed along at least one of opposite edge portions of the at least one impurity region.

The at least one opening may have an oval shape, a polygon shape, or a triangle shape.

A height of the at least one opening may be greater than a length of a base of the triangle shape opening. The height of the triangle shape opening may be greater than ½ of a width of the at least one impurity region underlying the triangle shape opening.

A direction from a base toward an apex opposite the base in one of two adjacent openings of the plurality of triangle shape openings may be opposite to a direction from a base toward an apex opposite the base in the other triangle shape opening.

The at least one impurity region may include an emitter layer of a second conductive type different from the first conductive type and a back surface field layer of the first conductive type that is separated from the emitter layer.

The passivation layer may include at least one first opening exposing a portion of the emitter layer and at least one second opening exposing a portion of the back surface field layer.

The first electrode may be connected to the exposed portion of the emitter layer exposed through the at least one first opening, and the second electrode may be connected to the exposed portion of the back surface field layer exposed through the at least one second opening.

The emitter layer and the back surface field layer may be positioned on a surface of the substrate on which light is not incident.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 schematically illustrates an opening of a layer according to an embodiment of the invention;

FIG. 2 is a cross-sectional view taken along line II-II of FIG. 1;

FIGS. 3A to 3C sequentially illustrate each of stages in a method for forming a layer according to an embodiment of the invention;

FIG. 4 schematically illustrates another example of an opening of a layer according to an embodiment of the invention;

FIGS. 5 and 6 are plane views of screen masks according to an embodiment of the invention;

FIG. 7 is a cross-sectional view of a substrate, in which a paste is printed on a layer using a screen mask, according to another embodiment of the invention;

FIG. 8 is a partial perspective view of a solar cell according to an embodiment of the invention;

FIG. 9 is a cross-sectional view taken along line IX-IX of FIG. 8;

FIG. 10 is a partial plane view of an opening of a back passivation layer of the solar cell shown in FIG. 8;

FIG. 11 is a partial perspective view of a solar cell according to an embodiment of the invention;

FIG. 12 is a partial plane view of an opening of a back passivation layer of the solar cell shown in FIG. 11;

FIG. 13 is a partial perspective view of a solar cell according to an embodiment of the invention;

FIG. 14 is a plane view schematically showing a back surface of the solar cell shown in FIG. 13;

FIG. 15 illustrates formation locations of an emitter layer or a back surface field layer and an opening;

FIG. 16 is a partial perspective view of a solar cell according to an embodiment of the invention; and

FIG. 17 is a plane view schematically showing a back surface of the solar cell shown in FIG. 16.

### DETAILED DESCRIPTION OF THE EMBODIMENTS

The invention will be described more fully hereinafter with reference to the accompanying drawings, in which example embodiments of the inventions are shown. This invention may, however, be embodied in many different forms and should not be construed as limited to the embodiments set forth herein.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, it will be understood that when an element such as a layer, film, region, or substrate is referred to as being “entirely” on another element, it may be on the entire surface of the other element and may not be on a portion of an edge of the other element.

Reference will now be made in detail to embodiments of the invention, examples of which are illustrated in the accompanying drawings.

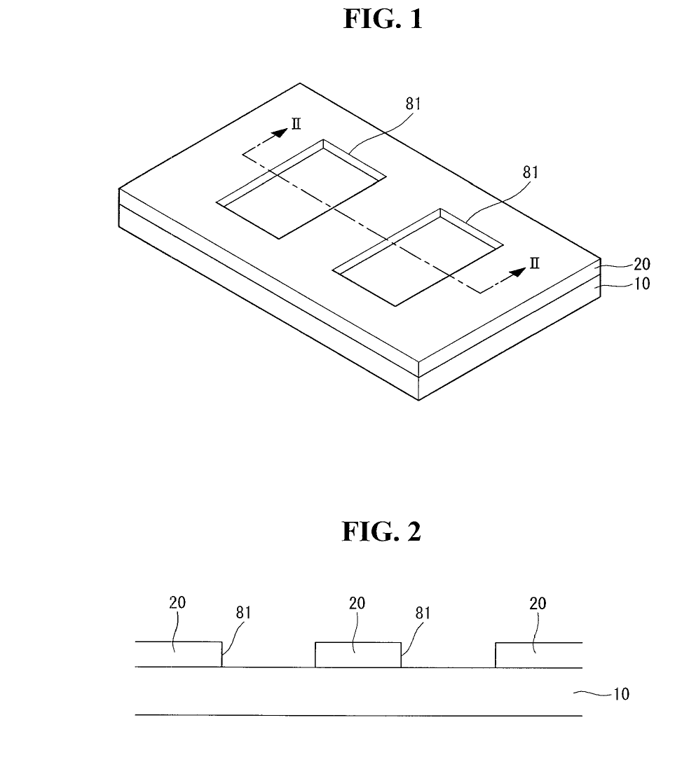

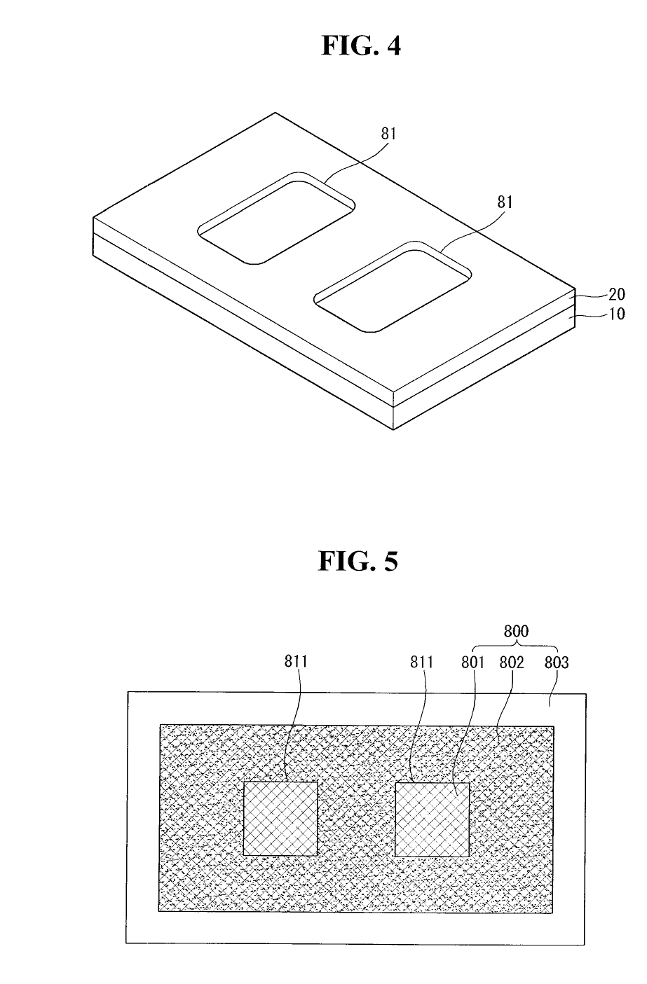

FIG. 1 schematically illustrates an opening of a layer according to an embodiment of the invention. FIG. 2 is a cross-sectional view taken along line II-II of FIG. 1. FIG. 4 schematically illustrates another example of an opening of a layer according to an embodiment of the invention.

In the embodiment of the invention, a panel shown in FIGS. 1 and 2 may be used as a panel for a solar cell, in which semiconductors each having a different conductive type form a p-n junction and electric power is produced using electrodes respectively connected to the semiconductors. The panel shown in FIGS. 1 and 2 may be used for various purposes.

The panel shown in FIGS. 1 and 2 includes a substrate 10 and a layer 20 positioned on the substrate 10.

The layer 20 may have a plurality of openings 81 each having a polygon shape, a polygon shape (refer to FIG. 4) having at least one straight portion and at least one curved edge (i.e., a curved portion), or an oval shape. In other words, the shape of each of the openings 81 is not a circle and has at least one straight portion. In the following description, a polygon shape indicates a polygon shape not including a circle, and a polygon shape having a curved portion indicates a polygon shape that does not include a circle and has at least one curved portion.

Examples of the substrate 10 include a transparent substrate formed of, for example, glass, a flexible substrate formed of, for example, plastic, and a semiconductor substrate formed of, for example, silicon.

When each of the openings 81 has a polygon shape having a curved portion, each opening 81 has at least two straight portions and at least two curved portions for connecting the at least two straight portions to each other. In the opening 81, the number of straight portions is equal to the number of curved portions. In the opening 81, a length ratio of one straight portion and two curved portions connected to the one straight portion may be approximately 1:49.5:49.5 to 98:1:1.

When at least one layer 20 is successively positioned on the substrate 10, the opening 81 removes a portion of the at least one layer 20 to expose a portion of the substrate 10 or a portion of other layer 20 (or portions of other layers 20) underlying the layer 20. If a desired material is coated or stacked on the opening 81, the coated or stacked material may serve as a terminal contacting the exposed portion of the substrate 10 or the exposed portion of the other layer(s) 20, a connection member, or an electrode. If a separate material is not coated or stacked on the opening 81, the opening 81 may serve as an exposure hole for exposing the portion of the substrate 10 or the portion of the other layer(s) 20.

In the solar cell, the opening 81 is used to form electrodes respectively connected to an emitter layer and a substrate or to manufacture a solar cell having a selective emitter structure in which an impurity concentration varies depending on a location of the emitter layer by removing a portion of the emitter layer. The opening 81 may be used for various purposes in the solar cell. For example, the opening 81 according to the embodiment of the invention may correspond to all of holes formed when removing a portion of a layer in other kinds of solar cells.

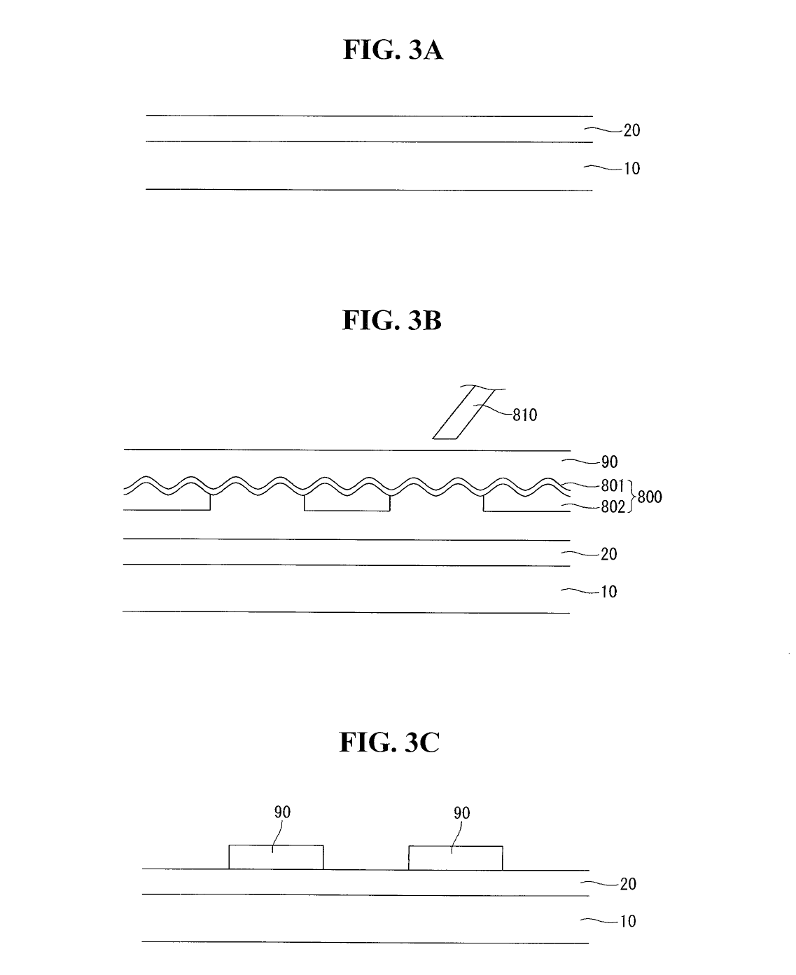

A method for forming the layer 20 having the openings 81 on the substrate 10 is described below with reference FIGS. 3A to 3C and FIGS. 5 to 7.

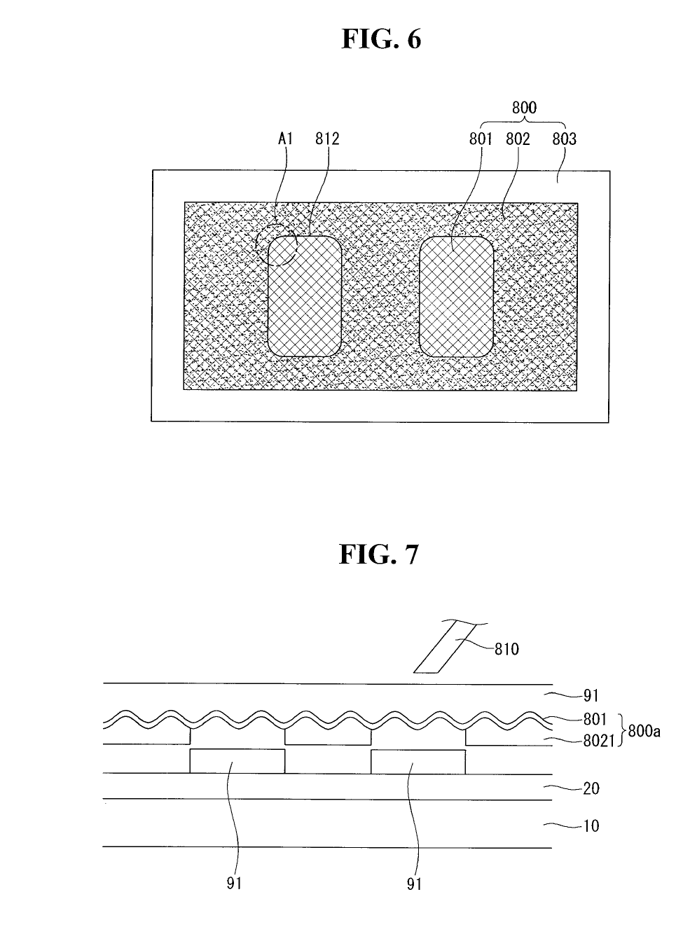

FIGS. 3A to 3C sequentially illustrate each of stages in a method for manufacturing a layer according to an embodiment of the invention. FIGS. 5 and 6 are plane views of screen masks according to an embodiment of the invention. FIG. 7 is a cross-sectional view of a substrate, in which a paste is printed on a layer using a screen mask, according to another embodiment of the invention.

As shown in FIG. 3A, a layer 20 is formed on a substrate 10. The layer 20 may be an insulating layer or a conductive layer. The layer 20 may be formed using various methods such as a sputtering method, a chemical vapor deposition (CVD) method, and an inkjet printing method.

Next, as shown in FIG. 3B, a screen mask 800 for screen printing is aligned on the layer 20.

As shown in FIGS. 5 and 6, the screen mask 800 includes a mesh net 801, a pattern forming part 802 positioned on the mesh net 801, and a frame 803 for fixing the mesh net 801.

The mesh net 801 has a net structure formed using threads having a fixed thickness. The size of each of openings formed between the threads varies depending on the thickness of the threads, the number of threads existing in the unit area, a pattern shape of the pattern forming part 802, a pattern size of the pattern forming part 802, and the like.

The pattern forming part 802 has a polygon pattern as shown in FIGS. 5 and 6. More specifically, the polygon pattern of the pattern forming part 802 has a rectangular injection part 811 as shown in FIG. 5 or a rectangular injection part 812 having curved edges A1 as shown in FIG. 6. The pattern forming part 802 may have a pattern having an oval injection part.

When the rectangular injection part 812 has the curved edges A1, the rectangular injection part 812 has at least two straight portions and at least two curved portions for connecting the at least two straight portions to each other. In the injection part 812, the number of straight portions is equal to the number of curved portions. In the injection part 812, a length ratio of one straight portion and two curved portions connected to the one straight portion may be approximately 1:49.5:49.5 to 98:1:1.

The pattern of the pattern forming part 802 is completed by coating and hardening an emulsion on the mesh net 801 and then removing the emulsion existing inside the injection part 811 (or 812) using a pattern mask.

Next, an etching paste 90 is pressed on the screen mask 800 using a squeezer 810, and thus the etching paste 90 is coated on the layer 20 through the injection part 811 (or 812). Thus, the etching paste 90 having the same shape as the injection part 811 (or 812) is coated on the layer 20 as shown in FIG. 3C.

Next, a portion of the layer 20 corresponding to the etching paste 90 is removed using the etching paste 90, and thus an opening 81 (refer to FIG. 2) is formed in the portion of the layer 20 on which the etching paste 90 is coated. The opening 81 has the same shape as the pattern of the pattern forming part 802. More specifically, the shape of the opening 81 is a polygon shape such as a rectangle, a polygon shape having a curved edge (for example, a rectangle shape having a curved edge), or an oval shape. In other words, the shape of the opening 81 has at least one straight portion.

Accordingly, in comparing a circle opening having a distance with the opening 81 of the polygon shape having the same width and height as the distance or the circle opening with the opening 81 of the oval shape having a width or a height equal to the distance, an opening area of the opening 81 is greater than an opening area of a circular opening, and shape uniformity of the opening 81 is improved. The circle opening is called an opening having a shape of a circle consisted of points having the same distance from a certain point

In other words, when the pattern forming part 802 of the screen mask 800 has a circular injection part not having a straight portion, the pattern size of the pattern forming part 802 is reduced by an area of edges of a polygon injection part. Hence, the pattern size of the pattern forming part 802 having the circular injection part is less than the pattern size of the pattern forming part 802 having a polygon shape (for example, a rectangle shape) or an oval shape. Accordingly, because the size of a circular opening is much less than the size of a polygon or oval opening entirely surrounding the circular opening, a contact area through the polygon or oval opening is greater than a contact area through the circular opening. Hence, a contact resistance through the polygon or oval opening is reduced, and a signal transmission efficiency through the polygon or oval opening is improved. Further, the number of threads existing in the unit area in a pattern forming area may increase, and thus a distance between the threads may decrease. In other words, because the distance between the threads (i.e., a distance between meshes) decreases, a phenomenon, in which the etching paste does not pass through a portion of the circular injection part, occurs. Hence, it is difficult to form a circular layer 20. However, in the embodiment of the invention, when the rectangular injection part 811 (or 812) or an oval injection part is used, an amount of the etching paste 90 passing through the injection part 811 (or 812) increases and the shape uniformity of the etching paste 90 is improved because of an increase in the size of the injection part 811 (or 812).

In particular, as shown in FIG. 6, when the pattern forming part 802 of the screen mask 800 has the polygon injection part 812 having the curved edges A1 or the oval injection part, a rectangular edge of the injection part, through which the etching paste 90 is difficult to pass, is removed. Hence, a printing operation of the etching paste 90 can be smoothly performed. Further, because the etching paste 90 printed on the layer 20 has a shape having at least one straight portion, the shape uniformity of the etching paste 90 printed on the layer 20 is further improved.

In the embodiment of the invention, the pattern forming part 802 of the screen mask 800 has the injection part 811 (or 812) exposing the mesh net 801 by removing the emulsion coated on a portion of the pattern forming part 802 having a polygon shape, a polygon shape having the curved edge, or an oval shape. However, in an alternative embodiment, unlike FIGS. 5 and 6, as shown in FIG. 7, a screen mask 800a has a structure in which an emulsion existing in a mesh net 801 of a portion having a polygon shape, a polygon shape having a curved edge, or an oval shape remains and the emulsion existing in the mesh net 801 of other portions is removed. In this case, a plurality of pattern forming parts 8021 each having a polygon shape, a polygon shape having a curved edge, or an oval shape are formed, and a paste 91 does not pass through the pattern forming parts 8021 and passes through a non-formation portion of the pattern forming parts 8021. Hence, the paste 91 is coated on the layer 20. The paste 91 printed on the layer 20 may serve as an etch stop layer for preventing the layer 20 underlying the paste 91 from being etched.

In the embodiment of the invention, in the shapes of the injection parts 811 and 812 and the shape of the opening 81, lengths of opposite sides may be equal to or different from each other.

Furthermore, in the embodiment of the invention, the opening 81 is formed using the screen printing method. Other methods may be used for the opening 81. For example, a gravure printing method and an inkjet printing method may be used.

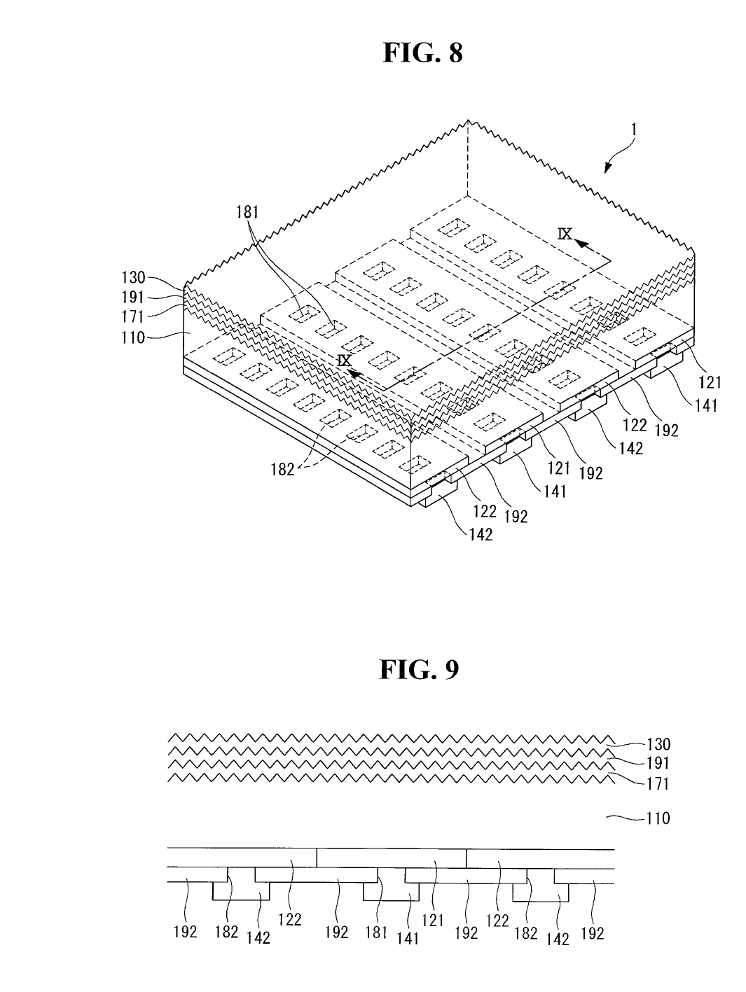

A solar cell according to the embodiment of the invention, to which a polygon opening (for example, a rectangular opening) is applied, is described below with reference to FIGS. 8 to 10.

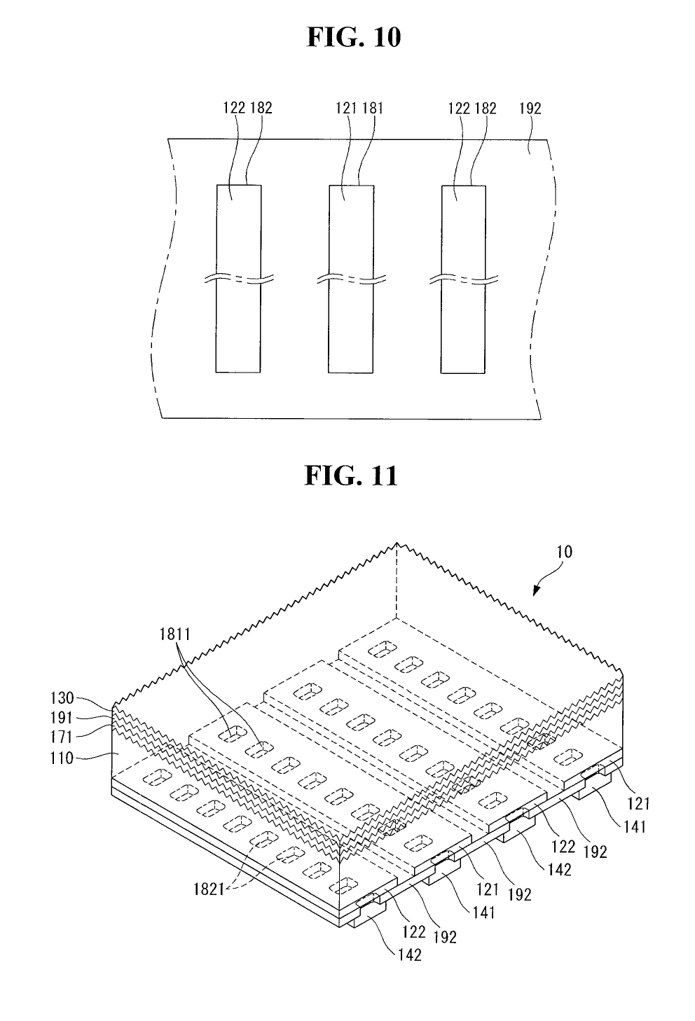

FIG. 8 is a partial perspective view of a solar cell according to an embodiment of the invention. FIG. 9 is a cross-sectional view taken along line IX-IX of FIG. 8. FIG. 10 is a partial plane view of an opening of a back passivation layer of the solar cell shown in FIG. 8.

As shown in FIG. 8, a solar cell 1 according to an embodiment of the invention includes a substrate 110, a front passivation layer 191 corresponding to a first passivation layer positioned on a surface (hereinafter, referred to as “a front surface”) of the substrate 110 on which light is incident, an anti-reflection layer 130 on the front passivation layer 191, a plurality of first impurity regions 121 on a surface (hereinafter, referred to as “a back surface”) of the substrate 110, opposite the front surface of the substrate 110, on which the light is not incident, a plurality of second impurity regions 122 that are positioned on the back surface of the substrate 110 to be spaced apart from the first impurity regions 121, a back passivation layer 192 corresponding to a second passivation layer positioned on the first impurity regions 121 and the second impurity regions 122, a plurality of first electrodes 141 respectively connected to the first impurity regions 121, a plurality of second electrodes 142 respectively connected to the second impurity regions 122, and a front surface field layer 171 positioned between the substrate 110 and the front passivation layer 191.

The substrate 110 is a semiconductor substrate formed of first conductive type silicon, for example, n-type silicon, though not required. Examples of silicon include crystalline silicon, such as single crystal silicon and polycrystalline silicon, and amorphous silicon. If the substrate 110 is of the n-type, the substrate 110 may contain impurities of a group V element such as phosphorus (P), arsenic (As), and antimony (Sb). Alternatively, the substrate 110 may be of a p-type. If the substrate 110 is of the p-type, the substrate 110 may contain impurities of a group III element such as boron (B), gallium (Ga), and indium (In). In addition, the substrate 110 may be formed of other semiconductor materials than silicon.

The front surface of the substrate 110 is textured to form a textured surface corresponding to an uneven surface. Hence, a light reflectance of the front surface of the substrate 110 is reduced. Further, because a light incident operation and a light reflection operation are many times performed on the textured surface of the substrate 110, the light is confined in the solar cell 1. Hence, a light absorption increases and the efficiency of the solar cell 1 is improved.

If the substrate 110 is formed of single crystal silicon, the front surface of the substrate 110 may be textured using a base compound such as NaOH and KOG. If the substrate 110 is formed of polycrystalline silicon, the front surface of the substrate 110 may be textured using an acid compound such as nitric acid (HNO₃) and hydrofluoric acid (HF).

The front surface field layer 171 on the front surface of the substrate 110 is formed by doping the substrate 110 with impurities (e.g., n-type impurities) of the same conductive type as the substrate 110 more heavily than the substrate 110. Hence, the movement of holes around the surface of the substrate 110 is prevented by a potential barrier resulting from a difference between impurity concentrations of the substrate 110 and the front surface field layer 171. Thus, a recombination and/or a disappearance of electrons and holes around the front surface of the substrate 110 are prevented or reduced.

The front passivation layer 191 corresponding to the first passivation layer positioned on the front surface field layer 171 is formed of silicon oxide (SiOₓ), for example. The front passivation layer 191 convert defects, such as a dangling bond, existing around the surface of the substrate 110 into stable bonds to thereby prevent or reduce a recombination and/or a disappearance of carriers moving to the front surface of the substrate 110. The front passivation layer 191 has a single-layered structure in the embodiment of the invention, but may have a multi-layered structure, such as a double-layered structure and a triple-layered structure.

The anti-reflection layer 130 on the front passivation layer 191 is formed of silicon nitride (SiNx) and/or titanium dioxide (TiO₂). If the anti-reflection layer 130 is formed of silicon nitride (SiNx), the front passivation layer 191 underlying the anti-reflection layer 130 may be omitted. The anti-reflection layer 130 reduces a reflectance of light incident on the substrate 110 and increases a selectivity of a predetermined wavelength band to thereby increase the efficiency of the solar cell 1. The anti-reflection layer 130 may have a thickness of about 70 nm to 80 nm. The anti-reflection layer 130 has a single-layered structure in the embodiment of the invention, but may have a multi-layered structure such as a double-layered structure. The anti-reflection layer 130 may be omitted, if desired.

The plurality of first impurity regions 121 and the plurality of second impurity regions 122 are alternately positioned on the back surface of the substrate 110 to be spaced apart from one another.

The first impurity regions 121 are spaced apart from one another and extend substantially parallel to one another in a fixed direction.

Each of the first impurity regions 121 is an impurity region obtained by heavily doping the substrate 110 with impurities (e.g., p-type impurities) of a second conductive type opposite the first conductive type of the substrate 110. Each of the first impurity regions 121 serves as an emitter layer, and thus the substrate 110 and the first impurity regions 121 form a p-n junction. The first impurity regions 121 contain impurities of a group III element such as boron (B), gallium (Ga), and indium (In).

The second impurity regions 122 are separated from the first impurity regions 121 and extend substantially parallel to one another in the same direction as an extension direction of the first impurity regions 121. Hence, the first impurity regions 121 and the second impurity regions 122 are alternately positioned on the back surface of the substrate 110.

Each of the plurality of second impurity regions 122 is an impurity region obtained by more heavily doping the substrate 110 with impurities (e.g., n-type impurities) of the same conductive type (i.e., the first conductive type) as the substrate 110 than the substrate 110.

The second impurity regions 122 serve as a back surface field layer in the same manner as the front surface field layer 171. Hence, carriers (e.g., holes) moving to the second impurity regions 122 are prevented or reduced from moving to the second electrodes 142 by a potential barrier resulting from a difference between impurity concentrations of the substrate 110 and the second impurity regions 122. Thus, a recombination and/or a disappearance of electrons and holes around the second electrodes 142 are prevented or reduced. A plurality of electron-hole pairs produced by light incident on the substrate 110 are separated into electrons and holes by a built-in potential difference resulting from the p-n junction between the substrate 110 and the first impurity regions 121. Then, the separated electrons move to the n-type semiconductor, and the separated holes move to the p-type semiconductor. Thus, when the substrate 110 is of the n-type and the first impurity regions 121 are of the p-type in the embodiment of the invention, the separated electrons move to the second impurity regions 122 and the separated holes move to the first impurity regions 121.

Because the substrate 110 and each of the first impurity regions 121 form the p-n junction, the first impurity regions 121 may be of the n-type if the substrate 110 is of the p-type unlike the embodiment of the invention described above. In this case, the separated electrons move to the first impurity regions 121 and the separated holes move to the second impurity regions 122.

The back passivation layer 192 corresponding to the second passivation layer positioned on the first impurity regions 121 and the second impurity regions 122 has a plurality of first openings 181 exposing a portion of each of the first impurity regions 121 and a plurality of second openings 182 exposing a portion of each of the second impurity regions 122. Each of the first and second openings 181 and 182 has a polygon shape such as a rectangle shape.

As shown in FIG. 8, the plurality of first openings 181 are positioned to be spaced apart from one another at a constant distance along a formation direction of the first impurity regions 121. The plurality of second openings 182 are positioned to be spaced apart from one another at a constant distance along a formation direction of the second impurity regions 122.

On the other hand, in an alternative embodiment, as shown in FIG. 10, each of the first impurity regions 121 may have only one opening formed along each first impurity region 121, and each of the second impurity regions 122 may have only one opening formed along each second impurity region 122.

The back passivation layer 192 are formed of silicon nitride (SiNx), silicon dioxide (SiO₂), or a combination thereof and may have a thickness equal to or greater than about 300 nm. The back passivation layer 192 shows a passivation effect capable converting unstable bonds existing around the surface of the substrate 110 into stable bonds in the same mariner as the front passivation layer 191 to thereby prevent or reduce a recombination and/or a disappearance of carriers moving to the back surface of the substrate 110. Further, the back passivation layer 192 reflects light passing through the substrate 110 inside the solar cell 1, so that light incident on the substrate 110 is not reflected outside the solar cell 1. Hence, an amount of light reflected outside the solar cell 1 is reduced. The back passivation layer 192 has a single-layered structure in the embodiment of the invention, but may have a multi-layered structure, such as a double-layered structure and a triple-layered structure.

The first electrodes 141 are formed on portions of the first impurity regions 121 exposed through the first openings 181 and on the back passivation layer 192 around the first openings 181. The second electrodes 142 are formed on portions of the second impurity regions 122 exposed through the second openings 182 and on the back passivation layer 192 around the second openings 182.

The first electrodes 141 extend along the first impurity regions 121 and are electrically and physically connected to the first impurity regions 121. The second electrodes 142 extend along the second impurity regions 122 and are electrically and physically connected to the second impurity regions 122.

The first and second electrodes 141 and 142 are spaced apart from one another at a constant distance and extend substantially parallel to one another along the first and second openings 181 and 182 in one direction. The first electrodes 141 collects carriers (e.g., electrons) moving to the first impurity regions 121 to transfer the carriers to an external device, and the second electrodes 142 collect collects carriers (e.g., holes) moving to the second impurity regions 122 to transfer the carriers to the external device.

As described above, because a portion of the first electrode 141 and a portion of the second electrode 142 overlap a portion of the back passivation layer 192, each of the first and second electrodes 141 and 142 includes a tip portion having a large area. Hence, when the first and second electrodes 141 and 142 are connected to an external device such as an external driving circuit, a contact resistance decreases and a contact efficiency increases.

The first and second electrodes 141 and 142 are formed of at least one conductive metal material. Examples of the conductive metal material include at least one selected from the group consisting of nickel (Ni), copper (Cu), silver (Ag), aluminum (Al), tin (Sn), zinc (Zn), indium (In), titanium (Ti), gold (Au), and a combination thereof. Other conductive metal materials may be used.

For example, each of the first and second electrodes 141 and 142 may be formed by coating a conductive paste obtained by adding a conductive metal material, such as Al, to Ag in the first and second openings 181 and 182 and around the first and second openings 181 and 182 through a screen printing method.

In the embodiment of the invention, because the first and second openings 181 and 182 of the back passivation layer 192 have the polygon shape, the shape uniformity of the first and second openings 181 and 182 is improved. Further, a contact area between the first impurity region 121 and the first electrode 141 and a contact area between the second impurity region 122 and the second electrode 142 increase because of the first and second openings 181 and 182. Hence, a contact strength and carrier transmission efficiency are improved. Further, shape uniformity of the first and second electrodes 141 and 142 on the first and second openings 181 and 182 is improved, and operation uniformity between the first electrodes 141 and operation uniformity between the second electrodes 142 increase.

In the embodiment of the invention, the first and second electrodes 141 and 142 are formed using the screen printing method. Other methods may be used. For example, the first and second electrodes 141 and 142 may be formed using a chemical vapor deposition (CVD) method, such as a plasma enhanced CVD (PECVD) method

Because the back passivation layer 192 formed of an insulating material exists between the first and second electrodes 141 and 142, an electrical interference between the first and second electrodes 141 and 142 decreases.

The solar cell 1 according to the embodiment of the invention having the above-described structure is a back contact solar cell capable of increasing an incident area of light by forming the first electrodes 141 and the second electrodes 142 on the back surface of the substrate 110 on which light is not incident. An operation of the back contact solar cell 1 is described below.

When light irradiated to the solar cell 1 is incident on the substrate 110 through the anti-reflection layer 130 and the front passivation layer 191, a plurality of electron-hole pairs is generated in the substrate 110 by light energy based on the incident light. Further, a reflection loss of the light incident on the substrate 110 decreases by the anti-reflection layer 130, and thus an amount of the light incident on the substrate 110 further increases. The electron-hole pairs are separated from one another by the p-n junction between the substrate 110 and the first impurity regions 121, and the separated holes move to the p-type first impurity regions 121 and the separated electrons move to the n-type second impurity regions 122. The holes moving to the first impurity regions 121 are collected by the first electrodes 141 to output to an external device, and the electrons moving to the second impurity regions 122 are collected by the second electrodes 142 to output to an external device.

As described above, because the first and second openings 181 and 182 have the polygon shape such as the rectangle shape, the shape uniformity of the first and second openings 181 and 182 and the carrier transmission efficiency are improved.

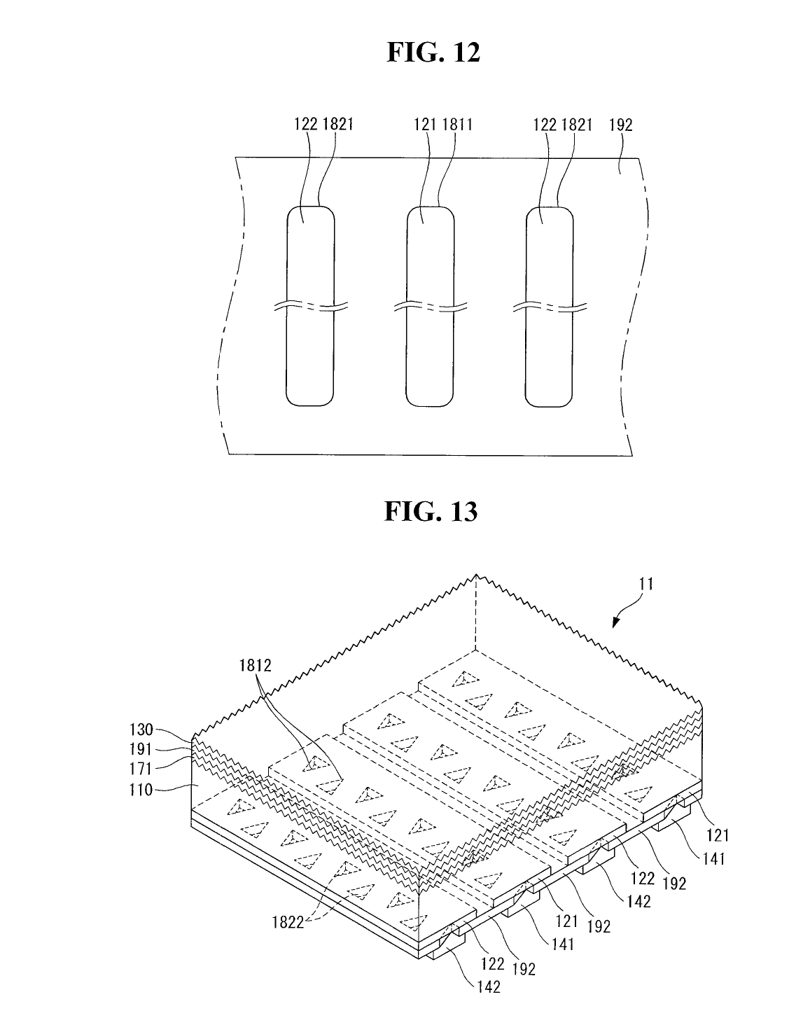

Next, a solar cell according to an embodiment of the invention, to which an opening of a polygon shape (for example, a rectangle shape) having a curved edge is applied, is described below with reference to FIGS. 11 and 12.

FIG. 11 is a partial perspective view of a solar cell according to an embodiment of the invention. FIG. 12 is a partial plane view of an opening of a back passivation layer of the solar cell shown in FIG. 11.

A solar cell 10 shown in FIGS. 11 and 12 has the same structure as the solar cell 1 shown in FIGS. 8 to 10 except a shape of an opening. Thus, structural elements of the solar cell 10 having the same functions and structures as the solar cell 1 are designated by the same reference numerals, and a further description may be briefly made or may be entirely omitted. Further, since a cross-sectional view taken along any line of FIG. 11 is substantially the same as FIG. 9 showing a cross-sectional view taken along line IX-IX of FIG. 8, a partial cross-sectional view of FIG. 11 is omitted.

As shown in FIG. 11, the solar cell 10 according to the embodiment of the invention includes a substrate 110, a front passivation layer 191 on a front surface of the substrate 110, an anti-reflection layer 130 on the front passivation layer 191, a plurality of first impurity regions 121 on a back surface of the substrate 110, a plurality of second impurity regions 122 on the back surface of the substrate 110, a back passivation layer 192 that is positioned on the first impurity regions 121 and the second impurity regions 122 and has a plurality of first and second openings 1811 and 1821, a plurality of first electrodes 141 respectively connected to the first impurity regions 121, a plurality of second electrodes 142 respectively connected to the second impurity regions 122, and a front surface field layer 171 between the substrate 110 and the front passivation layer 191.

In the solar cell 10, each of the plurality of first and second openings 1811 and 1821 of the back passivation layer 192 has a polygon shape (for example, a rectangle shape) having a curved edge, i.e., a curved portion.

As shown in FIG. 11, the plurality of first openings 1811 are spaced apart from one another at a constant distance along each of the first impurity regions 121, and the plurality of second openings 1812 are spaced apart from one another at a constant distance along each of the second impurity regions 122. On the other hand, in an alternative embodiment, as shown in FIG. 12, only one opening may be formed along each of the first impurity regions 121, and only one opening may be formed along each of the second impurity regions 122.

Because the first and second openings 1811 and 1821 have curved edges providing the excellent shape uniformity and do not have rectangular edges into which a conductive paste is difficult to penetrate, a contact area and a contact strength between the first openings 1811 and the first electrodes 141 and a contact area and a contact strength between the second openings 1821 and the second electrodes 142 increase. Further, the shape uniformity of the first and second electrodes 141 and 142 on the first and second openings 1811 and 1821 is further improved. Thus, the carrier transmission efficiency of the first and second electrodes 141 and 142 is improved, and operation uniformity between the first electrodes 141 and operation uniformity between the second electrodes 142 increase.

In the solar cells 1 and 10 shown in FIGS. 8 to 12, the first openings 181 and 1811 are formed in the middle of the first impurity region 121, and the second openings 182 and 1821 are formed in the middle of the second impurity region 122. However, in an alternative embodiment, the first openings 181 and 1811 may be formed at an edge of the first impurity region 121, and the second openings 182 and 1821 may be formed at an edge of the second impurity region 122. More specifically, the first openings 181 and 1811 and the second openings 182 and 1821 may be formed in at least one of left and right sides (or upper and lower sides) based on a middle line of a width of each of the first impurity region 121 and the second impurity region 122 along an extension direction of each of the first impurity region 121 and the second impurity region 122.

Next, a solar cell according to an embodiment of the invention is described below with reference to FIGS. 13 to 15.

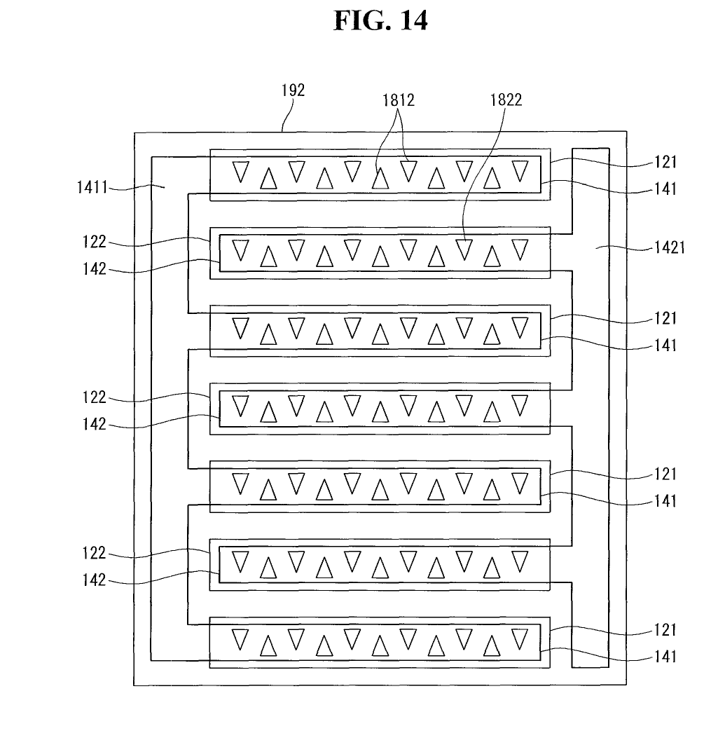

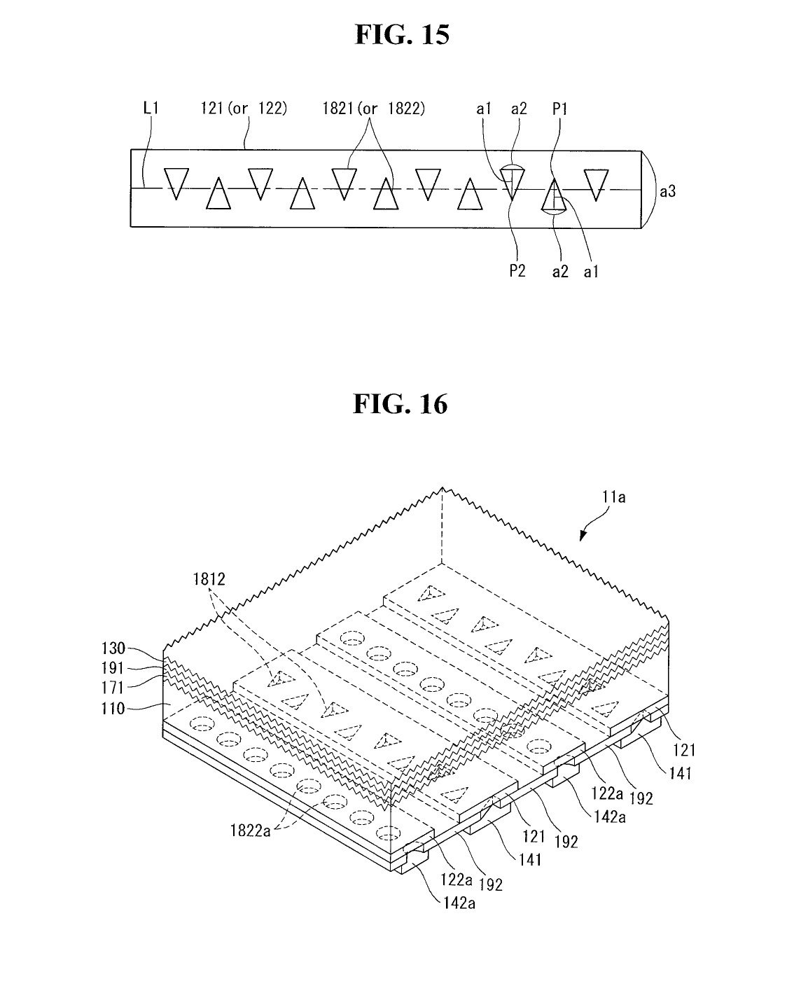

FIG. 13 is a partial perspective view of a solar cell according to an embodiment of the invention. FIG. 14 is a plane view schematically showing a back surface of the solar cell shown in FIG. 13. FIG. 15 illustrates formation locations of an emitter layer or a back surface field layer and an opening.

In the following explanations, structural elements having the same functions and structures as the solar cells 1 and 10 are designated by the same reference numerals, and a further description may be briefly made or may be entirely omitted.

A solar cell 11 according to an embodiment of the invention has a structure similar to the solar cell 1 shown in FIGS. 8 to 10.

As shown in FIGS. 13 and 14, the solar cell 11 according to the embodiment of the invention includes a substrate 110, a front surface field layer 171, a front passivation layer 191, an anti-reflection layer 130, a plurality of emitter layers 121 being a plurality of first impurity regions 121, a plurality of back surface field layers 122 being a plurality of second impurity regions 122, a back passivation layer 192 that is positioned on portions of the emitter layers 121 and portions of the back surface field layers 122 and has a plurality of first and second openings 1812 and 1822, a plurality of first electrodes 141 connected to exposed portions of the emitter layers 121, a plurality of second electrodes 142 connected to exposed portions of the back surface field layers 122, a plurality of first current collectors 1411 connected to the first electrodes 141, and a plurality of second current collectors 1421 connected to the second electrodes 142.

In the solar cell 11, the plurality of first and second openings 1812 and 1822 have a triangle shape. The plurality of first openings 1812 are positioned to be spaced apart from one another in a formation direction of the emitter layers 121, and the plurality of second openings 1822 are positioned to be spaced apart from one another in a formation direction of the back surface field layers 122.

In each of the triangle shaped first openings 1812 formed along the emitter layers 121, a base is positioned at an edge of the emitter layer 121, and an apex (hereinafter, referred to as “a base corresponding apex”) opposite the base is positioned in the middle of the emitter layer 121. Further, in each of the triangle shaped second openings 1822 formed along the back surface field layers 122 in the same manner as the first openings 1812, a base is positioned at an edge of the back surface field layer 122, and an apex opposite the base (i.e., a base corresponding apex) is positioned in the middle of the back surface field layer 122. Thus, when the triangle shaped first openings 1812 are positioned parallel to one another along the emitter layers 121, directions from the bases toward the base corresponding apexes of the successively positioned first openings 1812 are opposite to each other. Further, the triangle shaped second openings 1822 are positioned parallel to one another along the back surface field layers 122, directions from the bases toward the base corresponding apexes of the successively positioned second openings 1822 are opposite to each other. In other words, the triangle shaped first openings 1812 and the inverted triangle shaped first openings 1812 are alternately positioned along each of the emitter layers 121, and the triangle shaped second openings 1822 and the inverted triangle shaped second openings 1822 are alternately positioned along each of the back surface field layers 122. Hence, an opening area of the first and second openings 1812 and 1822 increases to a middle portion of each emitter layer 121 and a middle portion of each back surface field layer 122 as well as an edge portion of each emitter layer 121 and an edge portion of each back surface field layer 122.

In this ease, as shown in FIG. 15, in each of the first and second openings 1812 and 1822, a height a1 is greater than a length of a base a2 and is greater than a value (i.e., a3/2) obtained by dividing a width a3 of the emitter layer 121 (or the back surface field layer 122) by 2. Further, in each of the first and second openings 1812 and 1822, base corresponding apexes p1 and p2 are positioned at locations beyond a middle line L1 of a width of the emitter layer 121 (or the back surface field layer 122). Hence, the back passivation layer 192 has a larger opening area in the edge portions of the emitter layer 121 and the back surface field layer 122 than the middle portions of the emitter layer 121 and the back surface field layer 122 according to the openings 1812 and 1822.

As shown in FIG. 14, the first current collector 1411 connected to the first electrodes 141 is positioned on the back passivation layer 192 and collects carriers transferred through the first electrodes 141 to output the carriers to the outside. Further, the second current collector 1421 connected to the second electrodes 142 is positioned on the back passivation layer 192 and collects carriers transferred through the second electrodes 142 to output the carriers to the outside.

As described above, because the opening area of the back passivation layer 192 through the openings 1812 and 1822 increases to the middle portions of each emitter layer 121 and each back surface field layer 122 as well as the edge portions of each emitter layer 121 and each back surface field layer 122, each first electrode 141 contacts the middle portion of each emitter layer 121 as well as the edge portion of each emitter layer 121 and each second electrode 142 contacts the middle portion of each back surface field layer 122 as well as the edge portion of each back surface field layer 122.

Accordingly, the first electrodes 141 collect carriers in the middle portions of the emitter layers 121 as well as carriers (e.g., holes) in the edge portions of the emitter layers 121 to transfer the carriers to the first current collector 1411. The second electrodes 142 collect carriers in the middle portions of the back surface field layers 122 as well as carriers (e.g., electrons) in the edge portions of the back surface field layers 122 to transfer the carriers to the second current collector 1421.

However, because an opening area in the middle portions of the openings 1812 and 1822 is smaller than an opening area in the edge portions of the openings 1812 and 1822, an area of the back passivation layer 192 contacting the middle portions of the emitter layers 121 or the back surface field layers 122 is greater than an area of the back passivation layer 192 contacting the edge portions of the emitter layers 121 or the back surface field layers 122.

Thus, because carriers in the edge portions and the middle portions of each emitter layer 121 and each back surface field layer 122 are collected by the first and second electrodes 141 and 142, an amount of carriers transferred to the first and second current collectors 1411 and 1421 increases. Hence, the efficiency of the solar cell 11 is improved. Further, because a contact area between the back passivation layer 192 and the middle portions of each emitter layer 121 and each back surface field layer 122 is greater than a contact area between the back passivation layer 192 and the edge portions of each emitter layers 121 and each back surface field layers 122, a reduction width in the passivation effect of the back passivation layer 192 is not large even if the opening area of the back passivation layer 192 increases to the middle portions of each emitter layers 121 and each back surface field layers 122. Thus, the efficiency reduction of the solar cell 11 resulting from a recombination of carriers in the middle portions of each emitter layers 121 and each back surface field layers 122 is not large. The effect of the embodiment of the invention is described in detail.

In general, carrier density in middle portions of an emitter layer and a back surface field layer is greater than carrier density in edge portions of the emitter layer and the back surface field layer. Thus, when a plurality of circular openings are formed in the middle portions of the emitter layer and the back surface field layer, a contact area between a back passivation layer and the middle portions having the relatively high carrier density of the emitter layer and the back surface field layer decreases. Hence, the problem of a reduction in the passivation effect of the back passivation layer occurs. Therefore, a plurality of openings are formed in the edge portions of the emitter layer and the back surface field layer in a related art. However, because first and second electrodes collect carriers using the emitter layer and the back surface field layer contacting the first and second electrodes through the openings, the first and second electrodes collect carriers through the edge portions having the relatively low carrier density of the emitter layer and the back surface field layer. Hence, the collection efficiency of carriers was reduced in the related art.

Further, because a mobility of electrons is greater than a mobility of holes, a moving speed of electrons is greater than a moving speed of holes and an electrode contacting a p-type emitter layer or a p-type back surface field layer has to collect holes and has to transfer the holes to a corresponding current collector. However, when the circular openings are formed in the middle portions of the emitter layer and the back surface field layer, electrons are collected earlier than holes. Hence, the output efficiency of holes is reduced.

However, in the embodiment of the invention, the passivation layer 192 includes the openings 1812 and 1822 exposing both the edge portions and the middle portions of the emitter layer 121 and the back surface field layer 122, and the openings 1812 and 1822 have not a circle shape but a triangle shape varying an opening area depending on locations of the openings. Further, the opening areas of the openings 1812 and 1822 are not reduced as compared with opening areas of the related art openings. Hence, the carrier collection can be performed while a contact area between the passivation layer 192 and the middle portions having the relatively high carrier density is not reduced. Accordingly, the collection efficiency of carriers is improved while the passivation effect of the back passivation layer 192 is not reduced. Furthermore, because the carrier collection is performed in the middle portions having the relatively high carrier density while the opening area of each opening is not reduced, the collection efficiency of carriers is further improved.

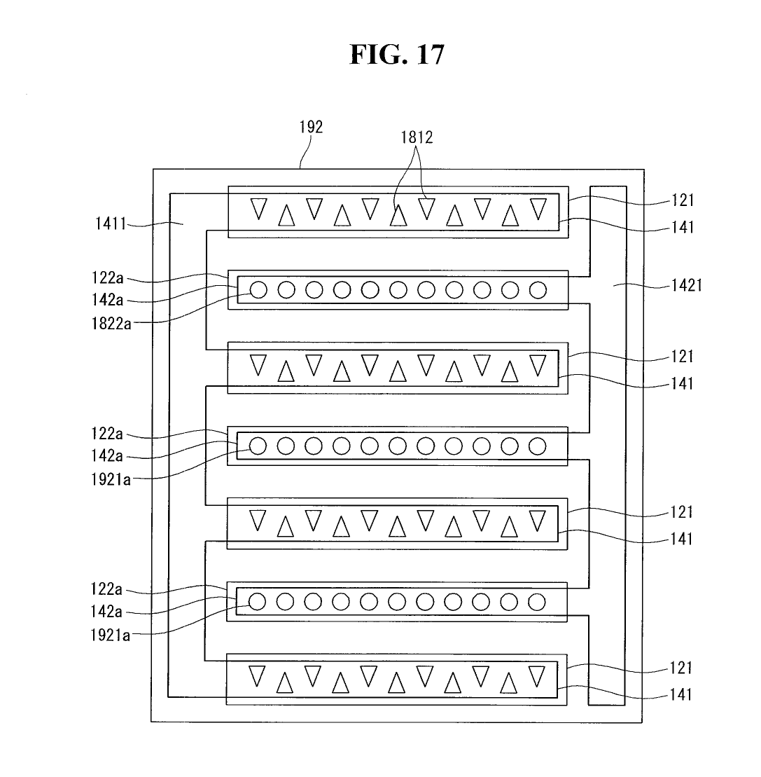

Next, a solar cell according to an embodiment of the invention is described below with reference to FIGS. 16 and 17.

FIG. 16 is a partial perspective view of a solar cell according to an embodiment of the invention. FIG. 17 is a plane view schematically showing a back surface of the solar cell shown in FIG. 16.

Since a solar cell 11a shown in FIGS. 16 and 17 is substantially the same as the solar cell 11 shown in FIGS. 13 and 14, except that shapes of a plurality of openings 1822a exposing a portion of each of a plurality of back surface field layers 122a, corresponding to second impurity regions, positioned on a back passivation layer 192, transverse widths of the back surface field layers 122a, and transverse widths of second electrodes 142a positioned on the back surface field layers 122a, a further description may be briefly made or may be entirely omitted.

In the solar cell 11a, openings 1812 and 1822a formed on the back passivation layer 192 have different shapes depending on a formation location. More specifically, the openings 1812 formed on the back passivation layer 192 along each emitter layer 121 have a triangle shape in the same manner as FIGS. 13 to 15, and the openings 1822a formed on the back passivation layer 192 along each back surface field layer 122a have a circle shape.

A width of each emitter layer 121 and a width of each back surface field layer 122 are equal to each other in the solar cell 11 shown in FIGS. 13 and 14, but a width of each emitter layer 121 and a width of each back surface field layer 122a are different from each other in the solar cell 11a shown in FIGS. 16 and 17. For example, the width of each emitter layer 121 is greater than the width of each back surface field layer 122a. Hence, a width of each first electrode 141 formed along each emitter layer 121 is greater than a width of each second electrode 142a formed along each back surface field layer 122a.

As above, when the width of the emitter layer 121 is greater than the width of the back surface field layer 122a, a sufficient space capable of forming the openings 1822a in the back surface field layers 122a is not secured and a generation area of carriers decreases. Thus, in this case, not triangular openings but the circular opening 1822a are formed along a middle portion of each back surface field layer 122a. Hence, carriers can be smoothly collected.

Further, in the solar cell 11a, because the triangle shaped openings 1812 and the inverted triangle shaped openings 1812 are alternately positioned along each emitter layer 121, the collection efficiency of carriers by the plurality of first electrodes 141 is improved. Hence, the efficiency of the solar cell 11a is improved.

Although the explanation was given of an example of a back contact solar cell, having the plurality of openings 181, 182, 1811, 1821, 1812, 1822, and 1822a, in which both the first and second electrodes 141 and 142 are positioned on the back surface of the substrate 110, in the embodiments of the invention, the embodiments of the invention may be applied to solar cells other than the back contact solar cell. As an alternative example of a solar cell having the openings according to the embodiments of the invention, a solar cell in which an electrode for collecting electrons and an electrode for collecting holes are respectively formed on a front surface and a back surface of a substrate may be applied. In this case, the openings may be formed in an anti-reflection layer, for example, formed on an emitter layer and may be used to bring the emitter layer into contact with the electrodes.

Although embodiments have been described with reference to a number of illustrative embodiments thereof, it should be understood that numerous other modifications and embodiments can be devised by those skilled in the art that will fall within the scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A solar cell, comprising;
a substrate having a first conductive type;
at least one impurity region connected to the substrate;
a passivation layer positioned on the at least one impurity region, the passivation layer including at least one opening exposing a portion of the at least one impurity region, the at least one opening having a shape having at least one straight portion;
a first electrode connected to the exposed portion of the at least one impurity region exposed through the at least one opening; and
a second electrode connected to the substrate.

2. The solar cell of clam 1, wherein the passivation layer includes a plurality of openings, the plurality of openings being formed along the at least one impurity region.

3. The solar cell of clam 2, wherein the plurality of openings are formed along at least one of opposite edge portions of the at least one impurity region.

4. The solar cell of clam 1, wherein the at least one opening has at least two straight portions and at least two curved portions connected to the at least two straight portions.

5. The solar cell of clam 4, wherein lengths of opposite sides of the at least one opening are equal to each other.

6. The solar cell of clam 5, wherein a length ratio of one of the at least two straight portions and two curved portions of the at least two curved portions connected to the one straight portion is approximately 1:49.5:49.5 to 98:1:1.

7. The solar cell of clam 4, wherein lengths of opposite sides of the at least one opening are different from each other.

8. The solar cell of clam 7, wherein a length ratio of one of the at least two straight portions and two curved portions of the at least two curved portions connected to the one straight portion is approximately 1:49.5:49.5 to 98:1:1.

9. The solar cell of clam 4, wherein the passivation layer includes a plurality of openings, the plurality of openings being formed along the at least one impurity region.

10. The solar cell of clam 9, wherein the plurality of openings are formed along at least one of opposite edge portions of the at least one impurity region.

11. The solar cell of clam 1, wherein the at least one opening has an oval shape.

12. The solar cell of clam 1, wherein the at least one opening has a polygon shape.

13. The solar cell of clam 12, wherein the at least one opening has a triangle shape.

14. The solar cell of clam 13, wherein a height of triangle shape is greater than a length of a base of the triangle shape.

15. The solar cell of clam 14, wherein the height of the triangle shape is greater than ½ of a width of the at least one impurity region underlying the triangle shape.

16. The solar cell of clam 13, wherein the passivation layer includes a plurality of openings having the triangle shape, the plurality of openings having the triangle shape being formed along the at least one impurity region.

17. The solar cell of clam 16, wherein a direction from a base toward an apex opposite the base in one of two adjacent openings of the plurality of openings having the triangle shape is opposite to a direction from a base toward an apex opposite the base in the other opening having the triangle shape.

18. The solar cell of clam 1, wherein the at least one impurity region includes an emitter layer of a second conductive type different from the first conductive type and a back surface field layer of the first conductive type that is separated from the emitter layer.

19. The solar cell of clam 18, wherein the passivation layer includes at least one first opening exposing a portion of the emitter layer and at least one second opening exposing a portion of the back surface field layer.

20. The solar cell of clam 19, wherein the first electrode is connected to the exposed portion of the emitter layer exposed through the at least one first opening, and the second electrode is connected to the exposed portion of the back surface field layer exposed through the at least one second opening.

21. The solar cell of clam 18, wherein the emitter layer and the back surface field layer are positioned on a surface of the substrate on which light is not incident.
